(19) United States
(12) Patent Application Publication
(10) Pub. No.: US 2017/0178795 A1
(43) Pub. Date: Jun. 22, 2017

(54) Through-Hole Inductor for Placement Over a Power Stage of a Power Converter

(71) Applicant: Infineon Technologies Austria AG, Villach (AT)

(72) Inventor: Emil Todorov, Fremont, CA (US)

(21) Appl. No.: 14/977,040

(22) Filed: Dec. 21, 2015

(51) Int. Cl. H01F 27/29; H05K 1/18; H05K 3/30; H01F 30/12

(52) U.S. Cl. CPC H01F 27/29; H01F 30/12; H05K 1/184; H05K 3/308

(57) ABSTRACT

An electrical conductor of a through-hole inductor includes a first section extending along a first side face of the magnetic core, a second section extending along a second side face of the magnetic core, and a third section connecting the first and second sections and extending through the magnetic core. A first straight lead extends downwards from the first section beyond the bottom main face of the magnetic core, and has an unbent distal end configured for through-hole mounting to a circuit board. A second straight lead extends downwards from the second section beyond the bottom main face, and also has an unbent distal end configured for through-hole mounting to the circuit board. The straight leads each have a height which allows for mounting of a power stage to the circuit board at least partly under the magnetic core.

### TECHNICAL FIELD

The instant application relates to power converters, and more particularly to through-hole inductors for power converters.

### BACKGROUND

Power converters such as DC-DC converters include several active and passive components, including a power stage for regulating the voltage of a load such as a processor. The power stage is coupled to the load by an output inductor. The components of a power converter, including the output inductor, are attached to a printed circuit board (PCB) together with the load. The PCB has various electrical pathways for electrically interconnecting the components of the power converter, and electrically connecting the power stage of the converter to the load. The power stages are conventionally attached to the PCB in the same plane as the output inductor, increasing the size of the PCB. Also, conventional layout design practices for PCBs further complicate such an arrangement of the power converter components.

### SUMMARY

According to an embodiment of a through-hole inductor for placement over a power stage of a power converter, the through-hole inductor comprises a magnetic core having top and bottom main faces and side faces extending between the top and bottom main faces, and an electrical conductor. The electrical conductor comprises a first section extending along a first one of the side faces of the magnetic core, a second section extending along a second one of the side faces opposite the first side face, and a third section connecting the first and second sections and extending through the magnetic core. The electrical conductor also comprises a first straight lead extending downwards from the first section beyond the bottom main face of the magnetic core and having an unbent distal end which is narrower than the remainder of the first straight lead so that the first straight lead has a wider part with a step for contacting a circuit board and the distal end is configured for through-hole mounting to the circuit board. The electrical conductor also comprises a second straight lead extending downwards from the second section beyond the bottom main face of the magnetic core and having an unbent distal end which is narrower than the remainder of the second straight lead so that the second straight lead has a wider part with a step for contacting the circuit board and the distal end is configured for through-hole mounting to the circuit board. The wider part of the first and second straight leads each have a height which allows for the power stage to be mounted to the circuit board at least partly under the magnetic core.

According to an embodiment of a power converter assembly, the power converter assembly comprises a circuit board having a first side and a second side opposite the first side, a power stage die of a power converter attached to the first side of the circuit board, and a through-hole inductor electrically connected to an output of the power stage die and disposed over the power stage die on the first side of the circuit board. The through-hole inductor comprises a magnetic core having top and bottom main faces and side faces extending between the top and bottom main faces, and an electrical conductor. The electrical conductor comprises a first section extending along a first one of the side faces of the magnetic core, a second section extending along a second one of the side faces opposite the first side face, and a third section connecting the first and second sections and extending through the magnetic core. The electrical conductor further comprises a first straight lead extending downwards from the first section beyond the bottom main face of the magnetic core and having an unbent distal end configured which is narrower than the remainder of the first straight lead so that the first straight lead has a wider part with a step contacting the first side of the circuit board and the distal end is through-hole mounted to the circuit board. The electrical conductor also comprises a second straight lead extending downwards from the second section beyond the bottom main face of the magnetic core and having an unbent distal end which is narrower than the remainder of the second straight lead so that the second straight lead has a wider part with a step contacting the first side of the circuit board and the distal end is through-hole mounted to the circuit board. The first and second straight leads each have a height which allows for the power stage to be mounted to the circuit board at least partly under the magnetic core.

According to an embodiment of a method of manufacturing a power converter assembly, the method comprises: attaching a power stage die of a power converter to a first side of a circuit board; and attaching a through-hole inductor to the first side of the circuit board so that the through-hole inductor is electrically connected to an output of the power stage die and disposed over the power stage die on the first side of the circuit board. The through-hole inductor comprises a magnetic core and an electrical conductor. The first conductor comprises a first section extending along a first side face of the magnetic core, a second section extending along a second side face of the magnetic core, and a third section connecting the first and second sections and extending through the magnetic core. The electrical conductor further comprises a first straight lead extending downwards from the first section beyond a bottom main face of the magnetic core and having an unbent distal end which is narrower than the remainder of the first straight lead so that the first straight lead has a wider part with a step. The electrical conductor also comprises a second straight lead extending downwards from the second section beyond the bottom main face of the magnetic core and having an unbent distal end which is narrower than the remainder of the second straight lead so that the second straight lead has a wider part with a step. The first and second straight leads each have a height which allows for the power stage to be mounted to the circuit board at least partly under the magnetic core. The through-hole inductor is attached to the first side of the circuit board by through-hole mounting the unbent distal end of the first and second straight leads to the circuit board after the power stage die is attached to the first side of the circuit board so that the step in the first and second straight leads contacts the first side of the circuit board.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIGS. 1A through 1F illustrate different views of a through-hole inductor shaped to accommodate a power stage die of a power converter under the inductor.

FIG. 2 illustrates a side perspective view of a magnetic core included in a through-hole inductor shaped to accommodate a power stage die of a power converter under the inductor.

FIGS. 3A through 3D illustrate different views of an electrical conductor for use with the magnetic core shown in FIG. 2.

FIG. 4 illustrates a side view of a through-hole inductor shaped to accommodate a power stage die of a power converter under the inductor, according to another embodiment.

FIG. 5 illustrates a top plan view of a power converter assembly that includes one or more through-hole inductors shaped to accommodate a power stage die of the power converter assembly under the inductors.

FIG. 6 illustrates a side perspective view of a 2-phase through-hole inductor shaped to accommodate a power stage die of a power converter under the inductor.

FIG. 7 illustrates a side perspective view of a 2-phase through-hole inductor shaped to accommodate a power stage die of a power converter under the inductor, according to another embodiment.

FIG. 8A illustrates a side perspective view of an embodiment of a non-coupled 2-phase through-hole inductor shaped to accommodate two power stages dies of two power converters placed completely or partially under the inductor.

FIG. 8B illustrates a side perspective view of an embodiment of a coupled 2-phase through-hole inductor shaped to accommodate two power stages dies of two power converters placed completely or partially under the inductor.

### DETAILED DESCRIPTION

According to embodiments described herein, each power stage die of a power converter such as a DC-DC converter is placed under the corresponding output inductor for that power stage e.g. in a buck topology in order to reduce the overall size of the power converter solution. Each power stage provides an output phase of the converter to a load. In the case of a single-phase DC-DC non-isolated converter, a single power stage is provided. In the case of a multi-phase DC-DC non-isolated converter, a power stage is provided for each phase of the converter. Each power stage die delivers a phase current through an output inductor to the load regulated by the power converter. Each power stage die can have a high-side transistor and a low-side transistor for coupling to the load through the corresponding output inductor. The high-side transistor of each power stage switchably connects the load to an input voltage of the power converter and the corresponding low-side transistor switchably connects the load to ground at different periods. Each power stage die can include active semiconductor components such as MOSFETs (metal oxide semiconductor field effect transistors), drivers, etc. and corresponding passive components. The passive components can be excluded from the die and provided as separate components. In general, each power stage die includes at least the active semiconductor components used to provide an output phase of the power converter to the load and is placed under the corresponding output inductor when attached to a circuit board such as a PCB to form a power converter assembly. The power stage die is not limited to a monolithic, single die power stage, but can also include an integrated package containing one or more dies including but not limited to the driver, the high side and the low side FET.

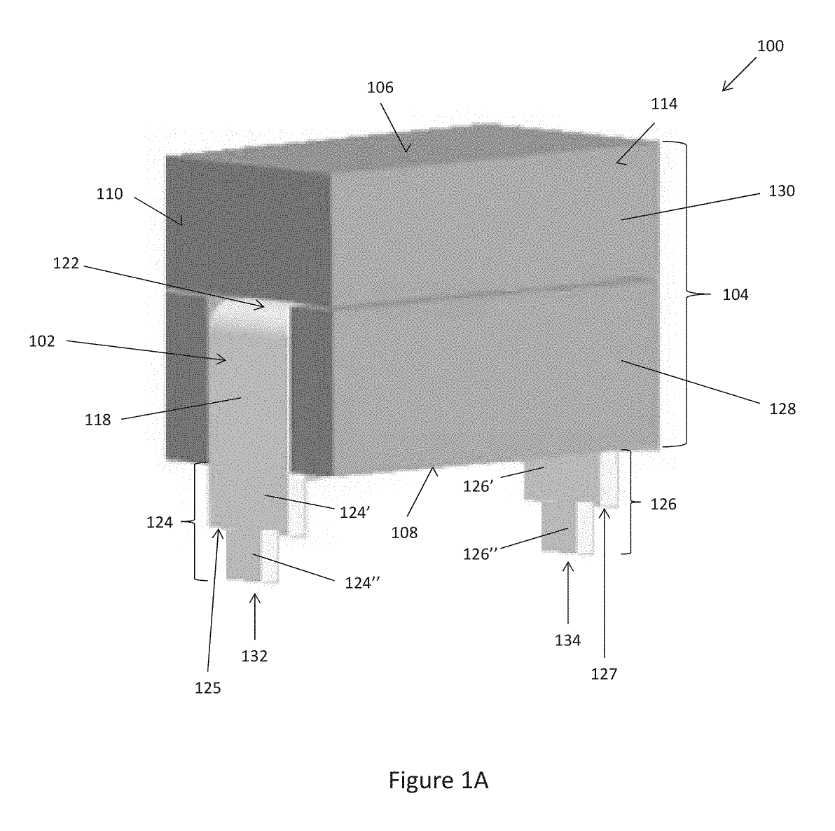

FIG. 1A shows a side perspective view of a through-hole inductor 100 shaped to accommodate a power stage die of a power converter under the inductor 100. FIG. 1B shows a top plan view of the through-hole inductor 100. FIG. 1C shows a bottom plan view of the through-hole inductor 100. FIG. 1D shows a side plan view of the through-hole inductor 100. FIG. 1E shows a front plan view of the through-hole inductor 100. FIG. 1F shows a top plan view of the circuit board footprint for the through-hole inductor 100. The term “through-hole” as used herein refers to a mounting scheme that involves the use of leads on electronic components that are inserted into holes drilled in circuit boards such as PCBs and soldered to pads or metal landings on the opposite side of the board either by manual assembly (hand placement) or by the use of solder wave from the bottom side of the board after an automated insertion mount machine installs the inductors along with other through-hole components.

The through-hole inductor 100 comprises an electrical conductor 102 and a magnetic core 104 having top and bottom main faces 106, 108 and side faces 110, 112, 114, 116 extending between the top and bottom main faces 106, 108. The electrical conductor 102 comprises a first section 118 extending along a first one of the side faces 110 of the magnetic core 104, a second section 120 extending along a second one of the side faces 112 opposite the first side face 110, and a third section 122 connecting the first and second 118, 120 sections and extending through the magnetic core 104. The electrical conductor 102 further comprises a first straight lead 124 extending downwards from the first section 118 beyond the bottom main face 108 of the magnetic core 104, and a second straight lead 126 extending downwards from the second section 120 beyond the bottom main face 108 of the magnetic core 104. The magnetic core 104 can include two or more sections 128, 130 between which the third section 122 of the electrical conductor is interposed. The magnetic core sections 128, 130 can be attached to one another e.g. by an adhesive to secure the electrical conductor 102 in place and ensure the straight leads 124, 126 of the conductor 102 are contactable via a standard through-hole process.

The first and second straight leads 124, 126 each have an unbent distal end 132, 134 configured for through-hole attachment to a circuit board. More particularly, the unbent distal end 132 of the first straight lead 124 is narrower than the remainder of the first straight lead 124 so that the first straight lead 124 has a wider upper part 124′ with a step or ledge 125 for contacting a circuit board and a narrower lower part 124″ configured for through-hole mounting to the circuit board. In a similar manner, the unbent distal end 134 of the second straight lead 126 is narrower than the remainder of the second straight lead 126 so that the second straight lead 126 has a wider upper part 126′ with a step or ledge 127 for contacting the circuit board and a narrower lower part 126″ configured for through-hole mounting to the circuit board.

The wider part 124′, 126′ of the first and second straight leads 124, 126 each have a height (D) and a width (F) which allows for a power stage to be mounted to the circuit board at least partly under the magnetic core 104 as will be described later in more detail, meaning that the power stage is partly or completely covered by the inductor 100. For example, one or more sides of the power stage may remain exposed so that pins along this side of the power stage are readily visible. The power stage is not shown in FIGS. 1A through 1F for ease of illustration of the through-hole inductor 100. The narrower part 124″, 126″ of the first and second straight leads 124, 126 each have a height (D′) and a width (F′) which allows for through-hole attachment to the circuit board through respective openings in the board. In one embodiment, the narrower part 124″ at the unbent distal end 132 of the first straight lead 124 is between 25% and 50% as wide as the wider part 124′ of the first straight lead 124, and the narrower part 126″ at the unbent distal end 134 of the second straight lead 126 is between 25% and 50% as wide as the wider part 126′ of the second straight lead 126.

The dimensions of the through-hole inductor 100 can vary significantly depending on the size of the power stage die or components at least partly accommodated under the inductor 100. In FIGS. 1B through 1E, the total length of the through-hole inductor 100 is labeled A, the total width is labeled B, and the total height with respect to the mounting board is labeled C. Also in FIGS. 1B through 1E, the height of the wider part 124′, 126′ of the straight leads 124, 126 of the electrical conductor 102 is labeled D, the spacing between the straight leads 124, 126 is labeled E, the width of the wider part 124′, 126′ of the straight leads 124, 126 is labeled F, and the thickness of the straight leads 124, 126 is labeled G. FIG. 1F which shows an exemplary board footprint for the through-hole inductor 100, in which H represents the outer spacing for the lead footprint on the circuit board, I represents the length for the lead footprint on the circuit board, and J represents the inner spacing for the lead footprint on the circuit board. The ovals 136, 138 shown in FIG. 1F represent exposed metal e.g. copper on the top side of the circuit board to which the through-hole inductor 100 is to be attached. The inner part of the ovals 136, 138 represents a plated opening via which extends through the board. The narrower part 124″, 126″ of the straight leads 124, 126 have a length (D′), width (F′) and thickness (G) which allows each narrower part 124″, 126″ to be inserted in the respective opening in the board and through-hole attached to the board. In FIG. 1F, K represents the center-to-center distance between the openings in the board. Upon insertion into the openings, the step 125/127 between the wider part 124′/126′ and narrower part 124″/126″ of each straight lead 124/126 contacts the corresponding exposed metal 136/138 on the top side of the board.

The wider part 124′, 126′ of the straight leads 124, 126 should be wide enough and tall enough to ensure that the magnetic core 104 can be raised to a given distance above the circuit board so as to provide enough clearance for placing a power stage die under the inductor 100 and so that the inductor 100 remains properly positioned on the circuit board during the through-hole installation process. For example in the case of the through-hole inductor having a length (A) of about 10 to 11 mm and a width (B) of about 8.5 to 9.5 mm, the height (D) of the wider part 124′, 126′ of each straight lead 124, 126 can range from about 1.0 to 1.5 mm, the total height (D+D′) of each straight lead can range from 6 to 7.5 mm, the width (F) of the wider part 124′, 126′ of each straight lead 124, 126 can range from about 3.5 to 5.5 mm, and the thickness (G) of each straight lead 124, 126 can range from about 0.5 to 1.0 mm. These dimensional ranges are only intended as illustrative examples. In a broad sense, the dimensions of the straight leads 124, 126 are a function of the overall inductor dimensions which in turn are a function of the dimensions of the power stage die to be at least partly accommodated under the inductor 100. The dimensions of the straight leads 124, 126 can be selected as desired so long as the leads 124, 126 are wide enough and tall enough to ensure that the magnetic core 104 can be raised to a particular distance needed to accommodate a power stage die at least partly under the inductor 100 and so that the inductor 100 remains properly positioned on the circuit board during the through-hole process as explained above. During power stage and inductor assembly on the same side of the board, these components do not touch each other and are not part of a monolithic (or molded in one piece) power module.

In general, the wider part 124′, 126′ of the straight leads 124, 126 of the electrical conductor 102 should have the same height (D) to ensure proper through-hole attachment of the inductor 100. The height (D) of the wider part 124′, 126′ of the straight leads 124, 126 must be great enough to accommodate a power stage die at least partly under the through-hole inductor 100. The straight leads 124, 126 extend from the respective first and second sections 118, 120 of the electrical conductor 102 below the bottom main face 108 of the magnetic core 104 to provide the necessary spacing to accommodate the power stage die. The wider part 124′, 126′ of each straight lead 124, 126 contacts the top side of the board at the respective step 125, 127. The wider part 124′ of the first straight lead 118 can have the same width (F) as the first section 118 of the electrical conductor 102, and the wider part 126′ of the second straight lead 126 can have the same width as the second section 120 of the electrical conductor 102. In other cases, the wider part 124′, 126′ of the straight leads 124, 126 can be wider or narrower than the corresponding section 118/120 of the electrical conductor 102 from which it extends.

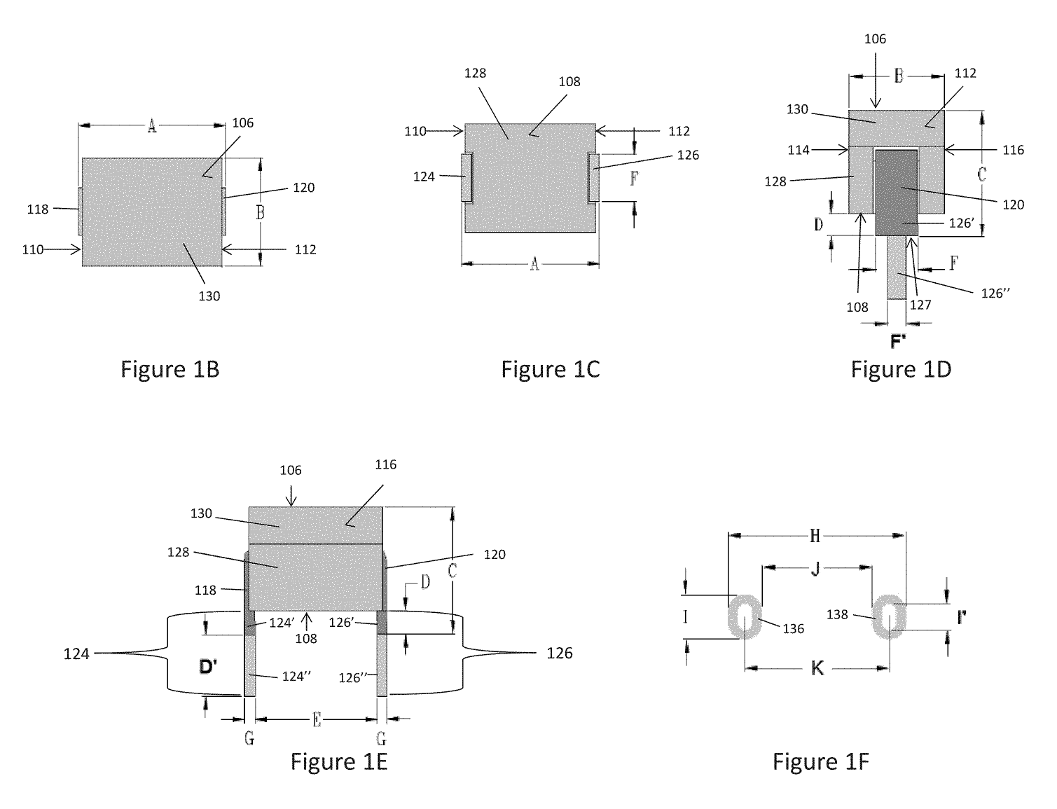

FIG. 2 illustrates one embodiment of the bottom section 128 of the magnetic core 104 included in the through-hole inductor 100 shown in FIGS. 1A through 1E. According to this embodiment, the first side face of 110 the magnetic core 104 has a first channel 200 for receiving the first section 118 of the electrical conductor 102, the second side face 112 of the magnetic core 104 has a second channel 202 for receiving the second section 120 of the electrical conductor 102, and the bottom section 128 of the magnetic core 104 has a third channel 204 for receiving the third section 122 of the electrical conductor 102.

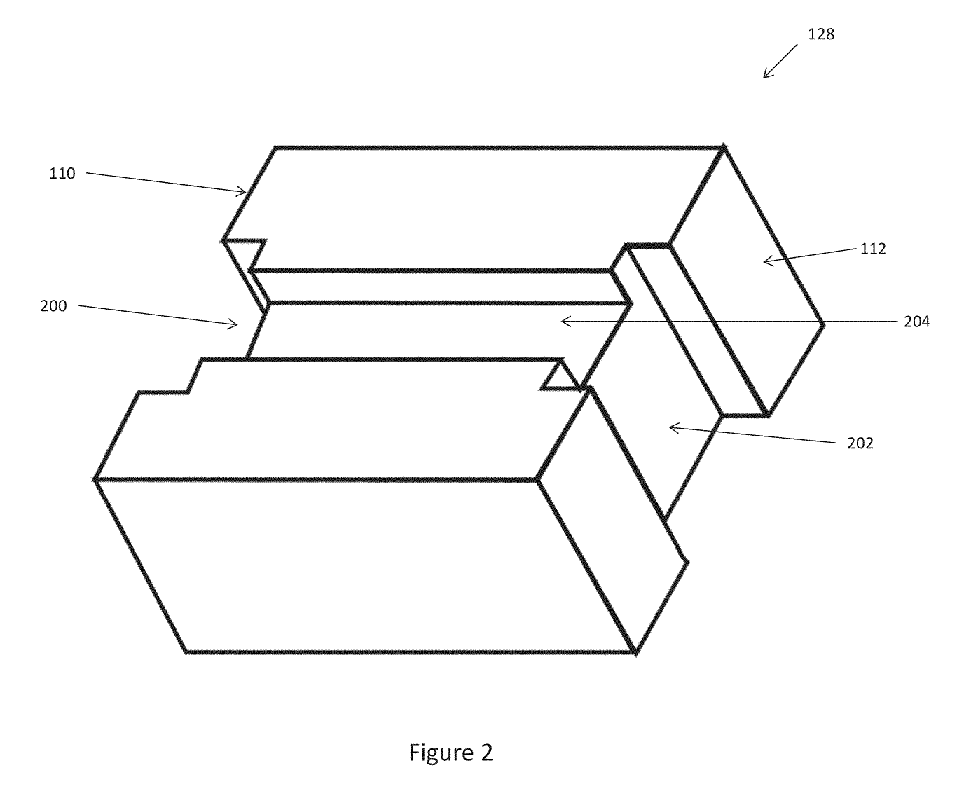

FIGS. 3A through 3D illustrate different views of the electrical conductor 102 included in the through-hole inductor 100 shown in FIGS. 1A through 1E. FIG. 3A shows a top plan view of the electrical conductor 102. FIG. 3B shows a side plan view of the electrical conductor 102.

FIG. 3C shows a front plan view of the electrical conductor 102. FIG. 3D shows a side perspective view of the electrical conductor 102. According to this embodiment, the third section 122 of the electrical conductor 102 is narrower than the first and second sections 118, 120. For example, the third section 122 of the electrical conductor 102 can have a width (W1) between 50% and 75% of the width (W2) of the first and second sections 118, 120. The electrical conductor 102 can be shaped like a staple, for example, and have a single continuous construction.

The electrical conductor 102 shown in FIGS. 3A through 3D can be formed by taking a straight metal conductor having a smaller width (W1) in the middle and a larger width (W2) toward the ends, and bending the conductor at the width transition points so that the electrical conductor has a first bend 300 between the first and third sections 118, 122 and a second bend 302 between the second and third sections 120, 122. The width of the electrical conductor 102 is greater between the first bend 300 and the first straight lead 124 and between the second bend 302 and the second straight lead 126 than between the first and second bends 300, 302 according to this embodiment i.e. W2>W1. With such a configuration, the third (middle) section 122 of the electrical conductor 102 provides higher inductance when passing through the magnetic core 104 and the wider end sections 118, 120 provide lower DCR i.e. the inherent resistance in the metal conductor of an inductor. Alternatively, all sections 118, 120, 122 of the electrical conductor 102 adjacent to the magnetic core 104 have the same width i.e. W2=W1.

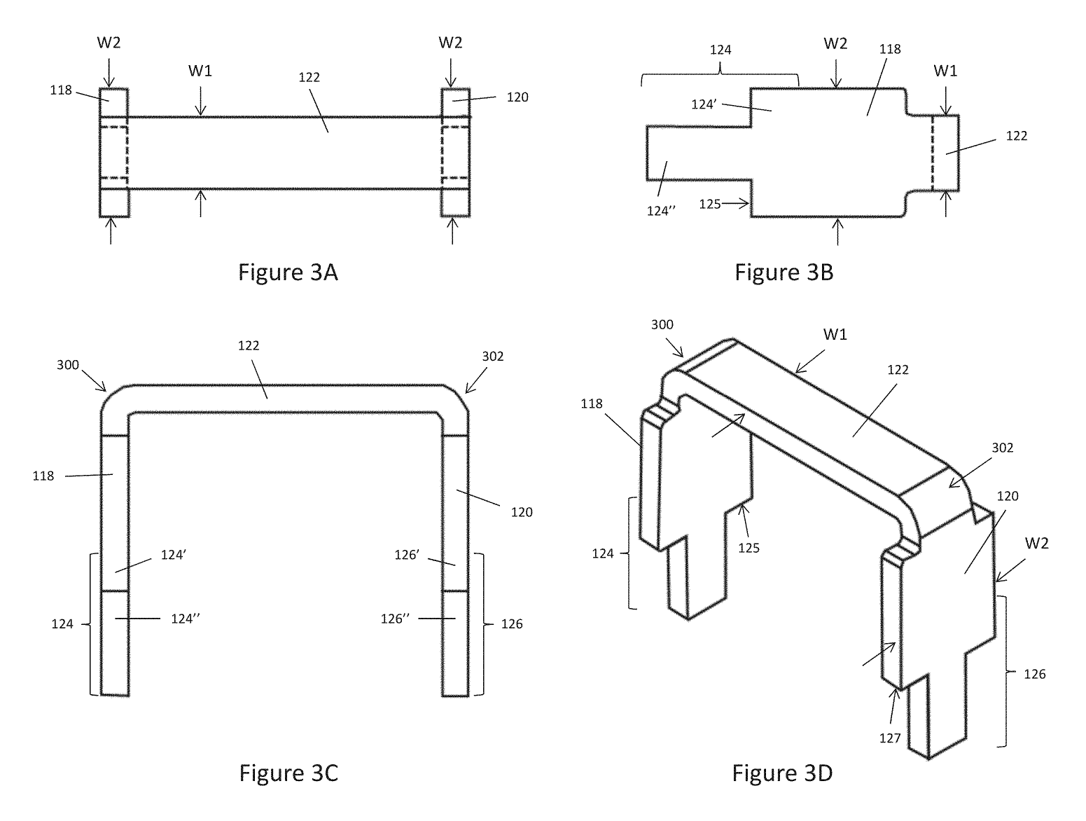

FIG. 4 illustrates a side view of the electrical conductor 102 included in the through-hole inductor 100 shown in FIGS. 1A through 1E, according to another embodiment. In this case, the first section 118 of the electrical conductor which extends along the first side face 110 of the magnetic core 104 does not have a uniform width over its entire length. Instead, the first section 118 of the electrical conductor 102 has a smaller width (W2_{A}) at the end further from the bottom main face 108 of the magnetic core 104 and a larger width (W2_{B}) at the end closer to the bottom main face 108 of the magnetic core 104. The second (opposing) section 120 of the electrical conductor 102 which extends along the second (opposing) side face 112 of the magnetic core 103 also does not have a uniform width over its entire length, but is out of view in FIG. 4.

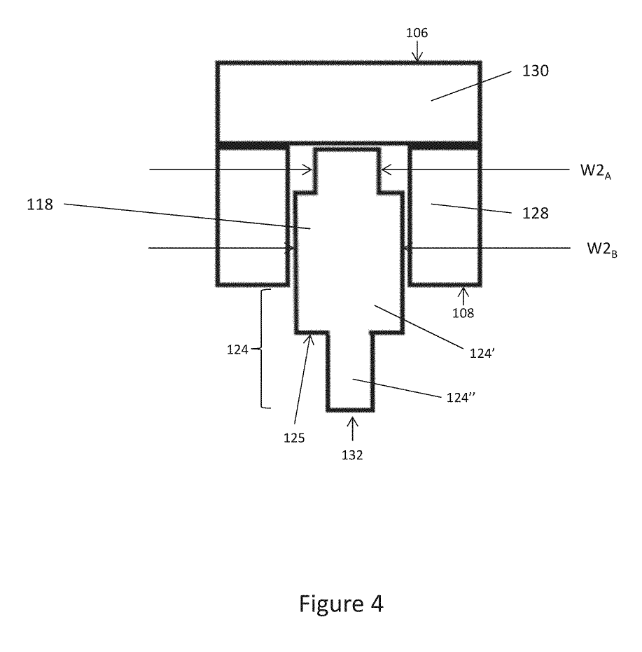

FIG. 5 illustrates a partial view of an embodiment of a power converter assembly 400 that includes one or more of the through-hole inductors described herein. According to this embodiment, the power converter assembly 400 comprises a circuit board 404 such as a PCB having a first main side and a second main side opposite the first side. At least one power stage die 406 of a power converter is attached to the first side of the circuit board 400. In one embodiment, the power converter is a DC-DC converter having a plurality of power stage dies 406 attached to the first side of the circuit board 400. In this case, the DC-DC converter is a multi-phase converter and each of the power stage dies 406 delivers a phase current through an output inductor 100 to a load regulated by the DC-DC converter. The VOUT node of the load is attached to the same side of the circuit board 400 as the power stage dies 406, and connected at the same side and the opposite side of the board 400 (where it is soldered) with regard to the load. The load can be any type of circuit requiring a regulated voltage such as one or more processors. The load and various components of the power converter such as the output capacitor, controller, etc. are out of view in FIG. 5. These components are not shown in FIG. 5 because their illustration is not necessary to aid in the understating of the present invention.

The left hand side of FIG. 5 illustrates one phase of the multi-phase DC-DC converter prior to attachment of the output inductor 100 to the first side of the circuit board 400, and the right hand side illustrates a second phase after attachment of the corresponding output inductor 100 to the first side of the circuit board 400. Each output inductor 100 is a through-hole inductor of the kind described herein. Also attached to the first side of the circuit board 400 are passive components 402 of the power converter such as input capacitors, output capacitors, resistors, etc. In one embodiment, some of the passive components 402 of the power converter can be accommodated under the output inductors 100. In either case, the passive components 402 and the power stage dies 406 are attached to the fist side of the circuit board 400 before the respective output inductors 100. One power stage die 406 is visible in the left hand side of FIG. 5. The footprint for the corresponding output inductor to be mounted to this part of the circuit board corresponds to the solid box labeled ‘PRE’ in FIG. 5. The output inductors 100 are attached to the first side of the circuit board 400 by passing the straight leads through plated openings 401, 403 formed through the board 400, after the passive components 402 and the power stage dies 406 are installed. One output inductor 100 is visible in the right hand side of FIG. 5. The boundary of the footprint for a conventional surface mount output inductor with bent leads is represented by the dashed box labeled ‘CON’ in FIG. 5.

The components attached to the circuit board 400, including the output inductors 100, are electrically connected to various terminals of the power stage dies 406 by electrically conductive vias 408 and/or traces 410 which are part of the circuit board 400. Each output inductor 100 is a through-hole inductor of the kind described herein, and is electrically connected to the output of the corresponding power stage die 406 and disposed over that die 406 on the first side of the circuit board 400. As such, each output inductor 100 has a magnetic core and an electrical conductor which includes a first section extending along a first side face of the magnetic core, a second section extending along an opposing second side face of the magnetic core, and a third section connecting the first and second sections and extending through the magnetic core. Each electrical conductor also includes a first straight lead extending downwards from the first section beyond the bottom main face of the magnetic core and having an unbent distal end configured for through-hole attachment to the circuit board 400, and a second straight lead extending downwards from the second section beyond the bottom main face of the magnetic core and having an unbent distal end configured for through-hole attachment to the circuit board 400.

More particularly, the unbent distal end of each straight lead is narrower than the remainder of that straight lead so that each straight lead has a wider part with a step which contacts exposed metal 412/414 such as copper which surrounds each opening 401/43 at the first side of the circuit board 400. The narrower part of each straight lead is inserted into the corresponding plated opening 401, 403 which extends through the board 400. This way, the narrower part of each straight lead can be through-hole mounted to the circuit board 400 and soldered at the opposite side of the board 400 as the inductor 100. Also, the wider part of the first and second straight leads each have a height which allows for the corresponding power stage die 406 to be mounted to the circuit board 400 at least partly under the magnetic core as previously described herein.

After each inductor 100 is through-hole attached to the circuit board 400, the step in the wider part of each straight lead contacts the exposed metal 412/414 which surrounds the corresponding opening 401/403 at the first side of the circuit board 400. One of the exposed metal regions 412 is electrically connected to the output (VOUT) of the corresponding power stage die 406. The other exposed metal region 414 is electrically connected to the switched output (VSW) of the power converter.

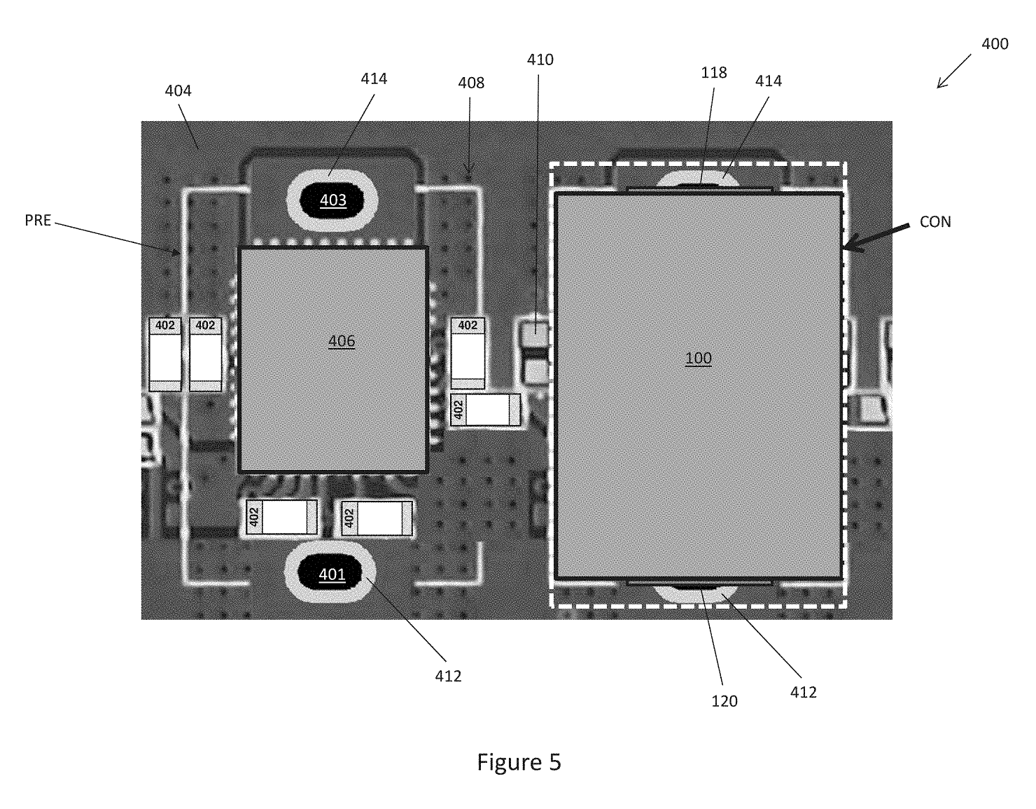

FIG. 6 illustrates a side perspective view of another embodiment of a through-hole inductor 500 shaped to accommodate one or more power stage dies of a power converter under the inductor 500. According to this embodiment, the through-hole inductor 500 is a 2-phase coupled or non-coupled inductor. That is, the through-hole inductor 500 also includes a second electrical conductor 502 spaced apart from the first electrical conductor 102. The first electrical conductor 102 is associated with a first phase of a power stage of a power converter, and the second electrical conductor 502 is associated with a second phase of the power stage. Similar to the first electrical conductor 102, the second electrical conductor 502 comprises a first section 504 extending along the first side face 110 of the magnetic core 104, a second section (out of view) extending along the second side face 112 of the magnetic core 104, and a third section 506 connecting the first and second sections and extending through the magnetic core 104.

In a non-coupled inductor configuration, the second electrical conductor 502 also comprises a first straight lead 508 extending downwards from the first section 508 beyond the bottom main face 108 of the magnetic core 104 and having an unbent distal end 510 configured for through-hole attachment to a circuit board, and a second straight lead 512 extending downwards from the second section beyond the bottom main face 108 of the magnetic core 104 and also having an unbent distal end 514 configured for through-hole attachment to the circuit board. More particularly, the unbent distal end 510 of the first straight lead 508 of the second electrical conductor 502 is narrower than the remainder of the first straight lead 508 so that the first straight lead 508 has a wider upper part 508′ with a step 505 for contacting a circuit board and a narrower lower part 508″ configured for through-hole mounting to the circuit board. In a similar manner, the unbent distal end 514 of the second straight lead 512 of the second electrical conductor 502 is narrower than the remainder of the second straight lead 512 so that the second straight lead 512 has a wider upper part 512′ with a step 507 for contacting the circuit board and a narrower lower part 512″ configured for through-hole mounting to the circuit board.

In a two-phase coupled inductor configuration, both electrical conductors 102, 502 enter and exit the magnetic core 104 at the same side of the magnetic material. Respectfully, the other phase electrical conductor (out of view) ending with extended leads of 512 and 126 corresponds to the VSW and VOUT nodes of that second phase. In either configuration, the wider part 508′, 512′ of the straight leads 508, 512 of the second electrical conductor 502, like the wider part 124′, 126′ of the straight leads 124, 126 of the first electrical conductor 102, each have a height which allows for one or more power stage dies to be mounted to the circuit board at least partly under the magnetic core 104. This concept can be generally extended to an M-phase through-hole inductor.

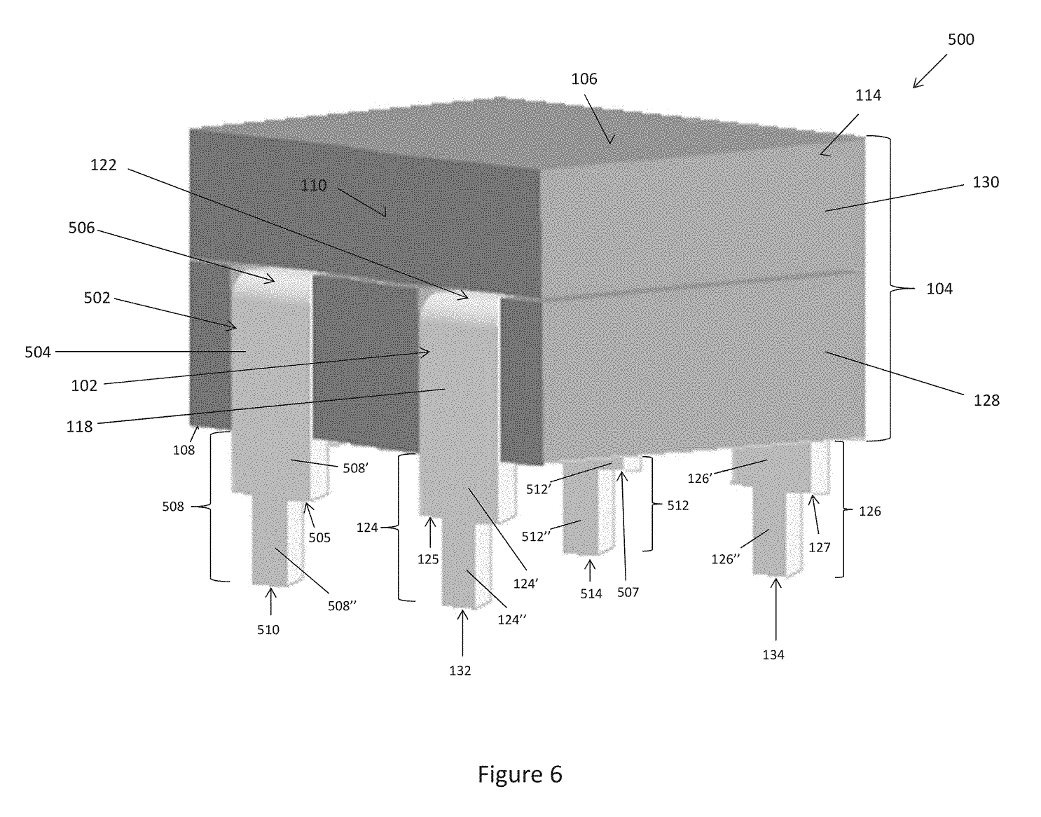

FIG. 7 illustrates a side view of yet another embodiment of a through-hole inductor shaped to accommodate two power stage dies of two power converters under the inductor. The embodiment shown in FIG. 7 is similar to the embodiment shown in FIG. 6. Different, however, each pair of opposing first and second sections of electrical conductors 102, 502 of the 2-phase coupled or non-coupled inductor do not have a uniform width over their respective lengths. Instead, the first section 118, 504 of each electrical conductor 102, 502 which extends along the first side face 110 of the magnetic core 104 has a smaller width (W2_{A1}, W2_{A2}) at the end further from the bottom main face 108 of the magnetic core 104 and a larger width (W2_{B1}, W2_{B2}) at the end closer to the bottom main face 108 of the magnetic core 104. The second (opposing) section of each electrical conductor 102, 502 which extends along the second (opposing) side face 112 of the magnetic core 104 also does not have a uniform width over its length, but is out of view in FIG. 7.

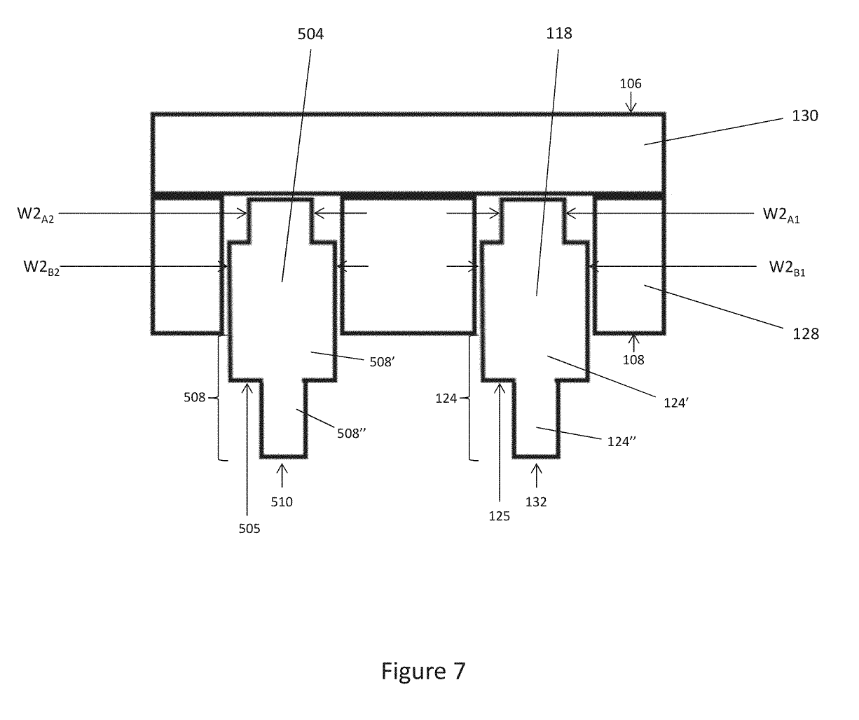

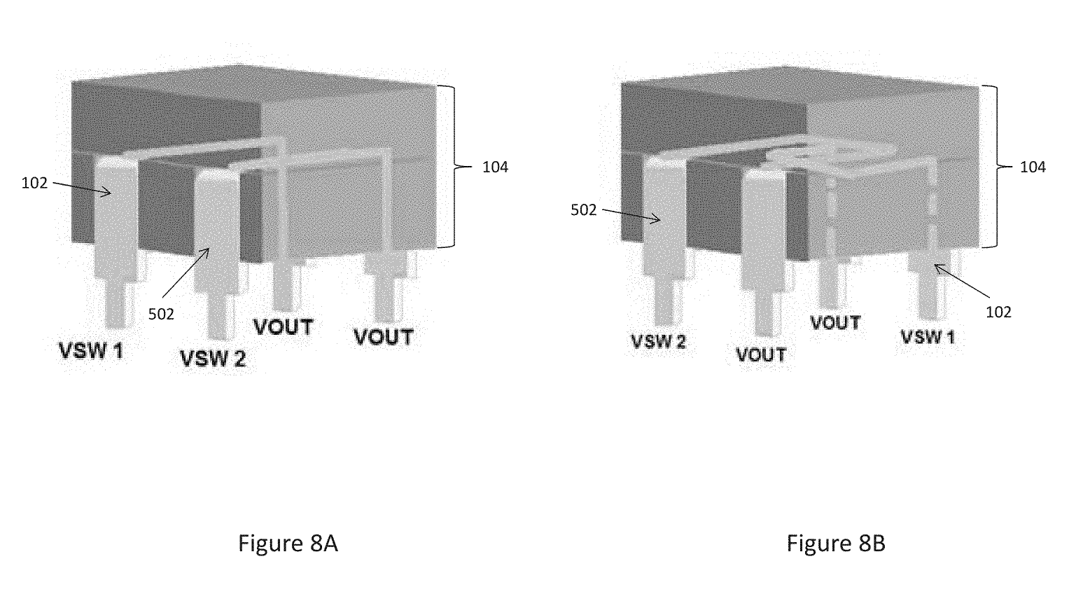

The multi-phase through-hole inductors shown in FIGS. 6 and 7 can be implemented as coupled or non-coupled inductors as explained above. FIG. 8A shows a non-coupled implementation of a 2-phase inductor, in which each electrical conductor 102, 502 enters and exits from opposite sides of the magnetic core 104. FIG. 8B shows a coupled implementation of a 2-phase inductor, in which one electrical conductor 102 enters and exits from one side of the magnetic core 104 and the other electrical conductor 502 enters and exits from the opposite side of the magnetic core 104. The VSW and VOUT nodes of the respective phases are labeled for each terminal of the electrical conductors 102, 502 in FIGS. 8A and 8B.

The through-hole inductors described herein have straight leads which have a step and an extended portion for allowing through-hole attachment, and which have sufficient height to allow for a power stage of a power converter to be accommodated at least partly under the inductor. The height of the straight leads depends on the dimensions of the inductor and of the power stage, but in some cases can range from 1.0 to 1.5 mm for the wider part of the straight leads which have a step for contacting the board and from 6 to 7.5 mm total height. During board manufacture, the straight-lead through-hole inductors can be assembled after power stage placement with other surface mount components via solder reflow, followed by visual optical inspection and only after that assembled with the remaining through-hole components, soldered through bottom side of the board using solder wave technique.

Compared to comparable surface mount inductors with bent leads, the through-hole inductors described herein have a shorter overall inductor length e.g. of about 2 mm for the same type of current application. The straight leads are wide enough e.g. 3.5 to 5.5 mm wide so as to significantly lower inductor DCR. For example, DCR in the range of 0.17-19 mΩ saves 1 W power at full load for a 5-phase server voltage regulator. The through-hole inductors described herein can be used with server CPUs (central processing units), graphics card GPUs (graphics processing units), telecommunication ASICs (application-specific integrated circuits) and FPGA (field-programmable gate array) applications, etc. to name a few.

Spatially relative terms such as “under”, “below”, “lower”, “over”, “upper” and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open-ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A through-hole inductor for placement over a power stage of a power converter, the through-hole inductor comprising:
a magnetic core having top and bottom main faces and side faces extending between the top and bottom main faces; and
a first electrical conductor, comprising:
a first section extending along a first one of the side faces of the magnetic core;
a second section extending along a second one of the side faces opposite the first side face;
a third section connecting the first and second sections and extending through the magnetic core;
a first straight lead extending downwards from the first section beyond the bottom main face of the magnetic core and having an unbent distal end which is narrower than the remainder of the first straight lead so that the first straight lead has a wider part with a step for contacting a circuit board and the distal end is configured for through-hole mounting to the circuit board; and
a second straight lead extending downwards from the second section beyond the bottom main face of the magnetic core and having an unbent distal end which is narrower than the remainder of the second straight lead so that the second straight lead has a wider part with a step for contacting the circuit board and the distal end is configured for through-hole mounting to the circuit board,
wherein the wider part of the first and second straight leads each have a height which allows for the power stage to be mounted to the circuit board at least partly under the magnetic core.

2. The through-hole inductor of claim 1, wherein the third section of the first electrical conductor is narrower than the first and second sections.

3. The through-hole inductor of claim 2, wherein the third section of the first electrical conductor has a width between 50% and 75% of the width of the first and second sections.

4. The through-hole inductor of claim 1, wherein the first side face of the magnetic core has a channel for receiving the first section of the first electrical conductor, wherein the second side face of the magnetic core has a channel for receiving the second section of the first electrical conductor, and wherein the magnetic core has a channel for receiving the third section of the first electrical conductor.

5. The through-hole inductor of claim 1, wherein the first and second sections of the electrical conductor have a thickness between 0.5 mm and 1 mm and a width between 3.5 mm to 5.5 mm.

6. The through-hole inductor of claim 1, wherein the first and second straight leads of the electrical each have a total height between 6 mm and 7.5 mm, and wherein the wider part of the first and second straight leads each have a height between 1.0 mm and 1.5 mm.

7. The through-hole inductor of claim 1, wherein the unbent distal end of the first straight lead is between 25% and 50% as wide as the wider part of the first straight lead, and wherein the unbent distal end of the second straight lead is between 25% and 50% as wide as the wider part of the second straight lead.

8. The through-hole inductor of claim 1, wherein the first electrical conductor has a first bend between the first and third sections and a second bend between the second and third sections, and wherein the width of the first electrical conductor is greater between the first bend and the wider part of the first straight lead and between the second bend and the wider part of the second straight lead than between the first and second bends.

9. The through-hole inductor of claim 1, further comprising a second electrical conductor spaced apart from the first electrical conductor, wherein the first electrical conductor is associated with a first phase of the power stage, wherein the second electrical conductor is associated with a second phase of the power stage, and wherein the second electrical conductor comprises:
a first section extending along the first side face of the magnetic core;
a second section extending along the second side face of the magnetic core;
a third section connecting the first and second sections and extending through the magnetic core;
a first straight lead extending downwards from the first section beyond the bottom main face of the magnetic core and having an unbent distal end which is narrower than the remainder of the first straight lead so that the first straight lead has a wider part with a step for contacting the circuit board and the distal end is configured for through-hole mounting to the circuit board; and
a second straight lead extending downwards from the second section beyond the bottom main face of the magnetic core and having an unbent distal end which is narrower than the remainder of the second straight lead so that the second straight lead has a wider part with a step for contacting the circuit board and the distal end is configured for through-hole mounting to the circuit board,
wherein the first and second straight leads of the second electrical conductor each have a height which allows for the power stage to be mounted to the circuit board at least partly under the magnetic core.

10. A power converter assembly, comprising:
a circuit board having a first side and a second side opposite the first side;
a power stage die of a power converter attached to the first side of the circuit board; and
a through-hole inductor electrically connected to an output of the power stage die and disposed over the power stage die on the first side of the circuit board, the through-hole inductor comprising:
a magnetic core having top and bottom main faces and side faces extending between the top and bottom main faces; and
a first electrical conductor, comprising:
a first section extending along a first one of the side faces of the magnetic core;
a second section extending along a second one of the side faces opposite the first side face;
a third section connecting the first and second sections and extending through the magnetic core;
a first straight lead extending downwards from the first section beyond the bottom main face of the magnetic core and having an unbent distal end which is narrower than the remainder of the first straight lead so that the first straight lead has a wider part with a step contacting the first side of the circuit board and the distal end is through-hole mounted to the circuit board; and
a second straight lead extending downwards from the second section beyond the bottom main face of the magnetic core and having an unbent distal end which is narrower than the remainder of the second straight lead so that the second straight lead has a wider part with a step contacting the first side of the circuit board and the distal end is through-hole mounted to the circuit board,
wherein the first and second straight leads each have a height which allows for the power stage to be mounted to the circuit board at least partly under the magnetic core.

11. The power converter assembly of claim 10, wherein the third section of the first electrical conductor is narrower than the first and second sections.

12. The power converter assembly of claim 11, wherein the third section of the first electrical conductor has a width between 50% and 75% of the width of the first and second sections.

13. The power converter assembly of claim 10, wherein the first side face of the magnetic core has a channel for receiving the first section of the first electrical conductor, wherein the second side face of the magnetic core has a channel for receiving the second section of the first electrical conductor, and wherein the magnetic core has a channel for receiving the third section of the first electrical conductor.

14. The power converter assembly of claim 10, wherein the first and second sections of the electrical conductor have a thickness between 0.5 mm and 1 mm and a width between 3.5 mm to 5.5 mm.

15. The power converter assembly of claim 10, wherein the first and second straight leads of the electrical each have a total height between 6 mm and 7.5 mm, and wherein the wider part of the first and second straight leads each have a height between 1.0 mm and 1.5 mm.

16. The power converter assembly of claim 10, wherein the unbent distal end of the first straight lead is between 25% and 50% as wide as the wider part of the first straight lead, and wherein the unbent distal end of the second straight lead is between 25% and 50% as wide as the wider part of the second straight lead.

17. The power converter assembly of claim 10, wherein the first electrical conductor has a first bend between the first and third sections and a second bend between the second and third sections, and wherein the width of the first electrical conductor is greater between the first bend and the wider part of the first straight lead and between the second bend and the wider part of the second straight lead than between the first and second bends.

18. The power converter assembly of claim 10, wherein the through-hole inductor further comprise a second electrical conductor spaced apart from the first electrical conductor, wherein the first electrical conductor is associated with a first phase of the power stage, wherein the second electrical conductor is associated with a second phase of the power stage, and wherein the second electrical conductor comprises:
a first section extending along the first side face of the magnetic core;
a second section extending along the second side face of the magnetic core;
a third section connecting the first and second sections and extending through the magnetic core;
a first straight lead extending downwards from the first section beyond the bottom main face of the magnetic core and having an unbent distal end which is narrower than the remainder of the first straight lead so that the first straight lead has a wider part with a step contacting the first side of the circuit board and the distal end is through-hole mounted to the circuit board; and
a second straight lead extending downwards from the second section beyond the bottom main face of the magnetic core and having an unbent distal end which is narrower than the remainder of the second straight lead so that the second straight lead has a wider part with a step contacting the first side of the circuit board and the distal end is through-hole mounted to the circuit board,
wherein the first and second straight leads of the second electrical conductor each have a height which allows for the power stage to be mounted to the circuit board at least partly under the magnetic core.

19. A method of manufacturing a power converter assembly, the method comprising:
attaching a power stage die of a power converter to a first side of a circuit board; and
attaching a through-hole inductor to the first side of the circuit board so that the through-hole inductor is electrically connected to an output of the power stage die and disposed over the power stage die on the first side of the circuit board, the through-hole inductor comprising a magnetic core and a first electrical conductor, the first electrical conductor comprising: a first section extending along a first side face of the magnetic core; a second section extending along a second side face of the magnetic core; a third section connecting the first and second sections and extending through the magnetic core; a first straight lead extending downwards from the first section beyond a bottom main face of the magnetic core and having an unbent distal end which is narrower than the remainder of the first straight lead so that the first straight lead has a wider part with a step; and a second straight lead extending downwards from the second section beyond the bottom main face of the magnetic core and having an unbent distal end which is narrower than the remainder of the second straight lead so that the second straight lead has a wider part with a step, the first and second straight leads each having a height which allows for the power stage to be mounted to the circuit board at least partly under the magnetic core,
wherein attaching the through-hole inductor to the first side of the circuit board comprises through-hole mounting the unbent distal end of the first and second straight leads to the circuit board after the power stage die is attached to the first side of the circuit board so that the step in the first and second straight leads contacts the first side of the circuit board.

20. A multi-phase coupled through-hole inductor for placement over power stages of a power converter, the through-hole inductor comprising:
a magnetic core having top and bottom main faces and side faces extending between the top and bottom main faces;
a first electrical conductor, comprising:
a first section extending along a first one of the side faces of the magnetic core;
a second section extending along the first side face of the magnetic core;
a third section connecting the first and second sections and extending in the magnetic core;
a first straight lead extending downwards from the first section beyond the bottom main face of the magnetic core and having an unbent distal end which is narrower than the remainder of the first straight lead so that the first straight lead has a wider part with a step for contacting a circuit board and the distal end is configured for through-hole mounting to the circuit board; and
a second straight lead extending downwards from the second section beyond the bottom main face of the magnetic core and having an unbent distal end which is narrower than the remainder of the second straight lead so that the second straight lead has a wider part with a step for contacting the circuit board and the distal end is configured for through-hole mounting to the circuit board; and
a second electrical conductor, comprising:
a first section extending along a second one of the side faces of the magnetic core opposite the first side face;
a second section extending along the second side face of the magnetic core;
a third section connecting the first and second sections and extending in the magnetic core;
a first straight lead extending downwards from the first section beyond the bottom main face of the magnetic core and having an unbent distal end which is narrower than the remainder of the first straight lead so that the first straight lead has a wider part with a step for contacting the circuit board and the distal end is configured for through-hole mounting to the circuit board; and
a second straight lead extending downwards from the second section beyond the bottom main face of the magnetic core and having an unbent distal end which is narrower than the remainder of the second straight lead so that the second straight lead has a wider part with a step for contacting a circuit board and the distal end is configured for through-hole mounting to the circuit board,
wherein the first and second straight leads of each electrical conductor have a height which allows for the power stages to be mounted to the circuit board at least partly under the magnetic core.
